(19) United States
(12) Patent Application Publication
(10) Pub. No.: US 2023/0377940 A1
(43) Pub. Date: Nov. 23, 2023

(54) MANUFACTURING METHOD OF CHIPS

(71) Applicant: DISCO CORPORATION, Tokyo (JP)

(72) Inventors: Yu ZHAO, Tokyo (JP); Shin TABATA, Tokyo (JP)

(21) Appl. No.: 18/321,411

(22) Filed: May 22, 2023

(30) Foreign Application Priority Data
May 23, 2022 (JP) 2022-083750

(51) Int. Cl. H01L 21/683; H01L 21/3065; B23K 26/40

(52) U.S. Cl. CPC H01L 21/6836; H01L 21/3065; B23K 26/40; H01L 2221/68327; H01L 2221/6834

(57) ABSTRACT

There is provided a manufacturing method of chips in which a wafer segmented into a plurality of regions by a plurality of planned dividing lines set in a lattice manner is divided to manufacture the chips. The manufacturing method of chips includes a groove forming step of holding the wafer including a first surface and a second surface by a holding table and forming grooves having a depth smaller than a thickness of the wafer along the planned dividing lines on the side of the first surface of the wafer, a first protective film coating step of coating the first surface of the wafer and side surfaces of the grooves with a first protective film, and a dividing step of dividing the wafer along the planned dividing lines. Plasma etching is executed for the wafer from the side of the first surface in the dividing step.

### BACKGROUND OF THE INVENTION

### Field of the Invention

The present invention relates to a manufacturing method of chips in which a wafer is divided to manufacture the chips.

### Description of the Related Art

In a manufacturing process of device chips, a wafer on which a device is formed in each of multiple regions marked out by multiple planned dividing lines (streets) arranged in a lattice manner is used. Multiple device chips each including the device are obtained by dividing this wafer along the planned dividing lines. The device chips are incorporated into various pieces of electronic equipment such as mobile phones and personal computers.

For the dividing of the wafer, a cutting apparatus that cuts a workpiece by an annular cutting blade, a laser processing apparatus that executes laser processing for a workpiece, or the like is used. Furthermore, in recent years, development of a process referred to as plasma dicing in which a wafer is divided by executing plasma etching for the wafer has also been advanced. In the plasma dicing, first, a mask patterned to expose planned dividing lines is formed on a wafer. Thereafter, an etching gas in a plasma state is supplied to the wafer through the mask. This causes plasma etching to be executed along the planned dividing lines, and the wafer is divided. However, it takes labor and time to form the mask, which causes increase in the number of steps and increase in cost. Thus, the following method has been proposed (refer to Japanese Patent Laid-open No. 2019-79884). Grooves with a predetermined depth are formed along planned dividing lines on a back surface side of a wafer. Then, plasma etching is executed for the back surface side of the wafer to thin the whole of the wafer. As a result, the grooves are caused to reach a front surface of the wafer to divide the wafer. Using this method makes it possible to divide the wafer without using a patterned mask and therefore the number of steps and the cost of the plasma dicing are reduced.

### SUMMARY OF THE INVENTION

As described above, by executing plasma etching for a wafer in which grooves are formed along planned dividing lines, the wafer can be divided without forming a mask. However, in the case of using this method, the plasma etching needs to be executed for the whole of the side of the surface in which the grooves are formed in the wafer to thin the wafer. As a result, a large amount of etching gas is consumed for the plasma etching and the cost increases. Furthermore, a treatment time of the plasma etching becomes long and processing efficiency of the wafer lowers.

The present invention is made in view of such a problem and intends to provide a manufacturing method of chips that can reduce the cost and improve the processing efficiency.

In accordance with an aspect of the present invention, there is provided a manufacturing method of chips in which a wafer segmented into a plurality of regions by a plurality of planned dividing lines set in a lattice manner is divided to manufacture the chips. The manufacturing method of chips includes a groove forming step of holding the wafer including a first surface and a second surface by a holding table and forming grooves having a depth smaller than a thickness of the wafer along the planned dividing lines on the side of the first surface of the wafer, a first protective film coating step of coating the first surface of the wafer and side surfaces of the grooves with a first protective film after the groove forming step, and a dividing step of dividing the wafer along the planned dividing lines after the first protective film coating step. Plasma etching is executed for the wafer from the side of the first surface in the dividing step.

Preferably, the dividing step includes a second protective film coating step of coating the side surfaces and bottom surfaces of the grooves with a second protective film thinner than the first protective film, an anisotropic plasma etching step of executing anisotropic plasma etching for the wafer from the side of the first surface to expose the bottom surfaces of the grooves, and an isotropic plasma etching step of executing isotropic plasma etching for the wafer from the side of the first surface to etch the bottom surfaces of the grooves.

The manufacturing method of chips may further include a protective film removal step of removing parts that coat bottom surfaces of the grooves in the first protective film to expose the bottom surfaces of the grooves by executing plasma etching for the wafer from the side of the first surface after the first protective film coating step and before the dividing step. Furthermore, the manufacturing method of chips may further include a plasma etching step of executing plasma etching for the wafer from the side of the first surface in a state in which the grooves are exposed after the groove forming step and before the first protective film coating step.

Moreover, the grooves may be formed in such a manner that an aspect ratio B/A of a width A of the grooves and a depth B of the grooves becomes equal to or higher than 1 in the groove forming step.

In the dividing step, the wafer may be divided along the planned dividing lines by executing the plasma etching for the wafer until the grooves reach the second surface of the wafer. Furthermore, in the dividing step, the wafer may be divided along the planned dividing lines by grinding the side of the second surface of the wafer and exposing the grooves in the second surface of the wafer after executing the plasma etching for the wafer.

The grooves may be formed by causing an annular cutting blade to cut into the wafer in the groove forming step. Moreover, the grooves may be formed by irradiating the wafer with a laser beam having absorbability with respect to the wafer in the groove forming step.

In the manufacturing method of chips according to the aspect of the present invention, after the first protective film is formed on the first surface side of the wafer in which the grooves are formed along the planned dividing lines, the plasma etching is executed for the first surface side of the wafer. Owing to this, the first protective film functions as a mask and the wafer is selectively etched along the planned dividing lines. When the above-described manufacturing method of chips is used, the plasma etching is executed for the inside of the grooves in the state in which the first surface side of the wafer is coated with the first protective film. This causes the etching gas to be efficiently supplied to the grooves. Therefore, the consumption amount of the etching gas is suppressed and the cost is reduced. Furthermore, the etching time is shortened and the processing efficiency of the wafer improves.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view illustrating a wafer;

FIG. 1B is a sectional view illustrating part of the wafer;

FIG. 2 is a perspective view illustrating the wafer to which a protective sheet is fixed;

FIG. 3 is a flowchart illustrating a manufacturing method of chips;

FIG. 4A is a partially sectional front view illustrating the wafer in which grooves are formed by a cutting apparatus;

FIG. 4B is a partially sectional front view illustrating the wafer in which the grooves are formed by a laser processing apparatus;

FIG. 5 is a partially sectional front view illustrating plasma treatment apparatus;

FIG. 6 is a partially sectional front view illustrating the wafer in a plasma etching step;

FIG. 7A is a partially sectional front view illustrating the wafer in a first protective film coating step;

FIG. 7B is a sectional view illustrating part of the wafer in which the side surfaces and bottom surfaces of the grooves are coated with a first protective film;

FIG. 7C is a sectional view illustrating part of the wafer in which the side surfaces of the grooves are coated with the first protective film;

FIG. 8 is a sectional view illustrating part of the wafer in a protective film removal step;

FIG. 9 is a flowchart illustrating an example of a dividing step;

FIG. 10A is a sectional view illustrating part of the wafer in a second protective film coating step;

FIG. 10B is a sectional view illustrating part of the wafer in an anisotropic plasma etching step;

FIG. 10C is a sectional view illustrating part of the wafer in an isotropic plasma etching step;

FIG. 11 is a sectional view illustrating part of the wafer obtained after the dividing step;

FIG. 12 is a flowchart illustrating another example of the dividing step; and

FIG. 13 is a front view illustrating the wafer in a grinding step.

### DETAILED DESCRIPTION OF THE PREFERRED EMBODIMENT

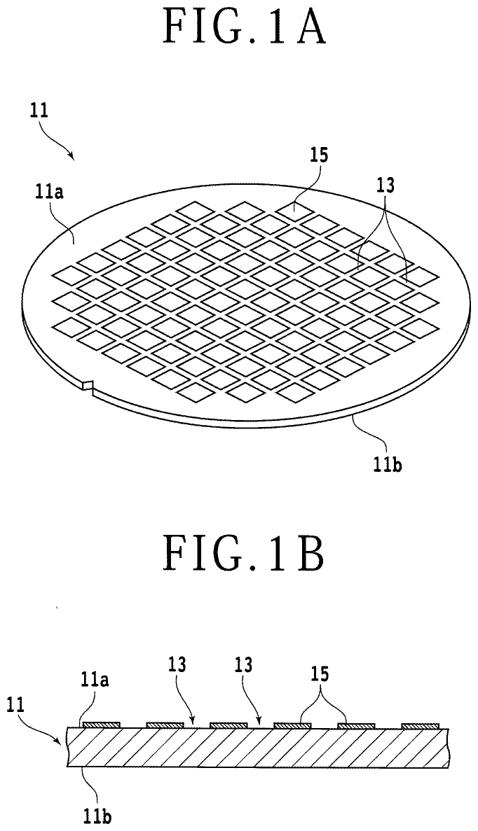

An embodiment according to one aspect of the present invention will be described below with reference to the accompanying drawings. First, a configuration example of a wafer that can be used in a manufacturing method of chips according to the present embodiment will be described. FIG. 1A is a perspective view illustrating a wafer 11. FIG. 1B is a sectional view illustrating part of the wafer 11.

For example, the wafer 11 is a circular disc-shaped wafer composed of a semiconductor material such as single-crystal silicon and includes a front surface 11a and a back surface 11b substantially parallel to each other. The wafer 11 is segmented into multiple rectangular regions by multiple planned dividing lines (streets) 13 arranged and set in a lattice manner to intersect each other. A device 15 such as an integrated circuit (IC), large scale integration (LSI), a light emitting diode (LED), or micro electro mechanical systems (MEMS) device is formed on a side of the front surface 11a of each of the multiple regions marked out by the planned dividing lines 13. However, there is no limitation on the material, shape, structure, size, and so forth of the wafer 11. For example, the wafer 11 may be a wafer (substrate) composed of a semiconductor other than silicon (GaAs, InP, GaN, SiC, or the like), sapphire, glass, ceramic, resin, metal, or the like. Furthermore, there is no limitation also on the kind, quantity, shape, structure, size, arrangement, and so forth of the devices 15.

Multiple chips (device chips) each including the device 15 are manufactured by dividing the wafer 11 along the planned dividing lines 13. For example, the wafer 11 is processed by using a processing apparatus such as a cutting apparatus, a laser processing apparatus, or a plasma treatment apparatus, and is divided into the multiple chips.

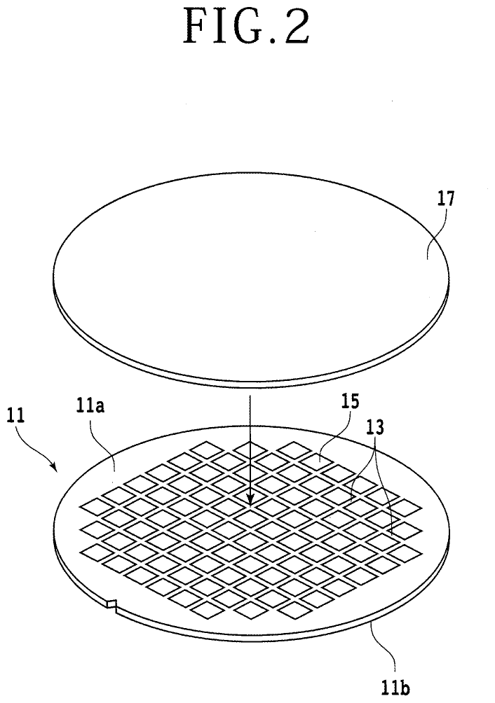

When the wafer 11 is processed by the processing apparatus, a protective sheet may be fixed to the wafer 11. FIG. 2 is a perspective view illustrating the wafer 11 to which a protective sheet 17 is fixed.

For example, the protective sheet 17 is a circular tape formed with substantially the same diameter as the wafer 11 and includes a film-shaped base and an adhesive (glue layer) disposed on the base. The base is composed of resin such as polyolefin, polyvinyl chloride, or polyethylene terephthalate. Moreover, the adhesive is composed of an epoxy-based, acrylic-based, or rubber-based adhesive, an ultraviolet-curable resin, or the like. The protective sheet 17 is stuck to the side of the front surface 11a of the wafer 11. Owing to this, the whole of the side of the front surface 11a of the wafer 11 is covered by the protective sheet 17, and the multiple devices 15 are protected.

The wafer 11 may be supported by an annular frame (not illustrated) for convenience of handling (conveyance, holding, and so forth) of the wafer 11. In this case, the annular frame composed of metal such as stainless steel (SUS) and the protective sheet 17 that has a larger diameter than the wafer 11 and has a circular shape are used. A circular opening part that penetrates the frame in the thickness direction is made at a central part of the annular frame. Furthermore, in the state in which the wafer 11 is disposed inside the opening part of the frame, a central part of the protective sheet 17 is stuck to the side of the front surface 11a of the wafer 11, and an outer circumferential part of the protective sheet 17 is stuck to the frame. This causes the wafer 11 to be supported by the frame through the protective sheet 17.

Moreover, the protective sheet 17 may be a sheet that can be thermocompression-bonded to the wafer 11 (thermocompression bonding sheet). The thermocompression bonding sheet is composed of a thermoplastic resin with a lower melting point than the wafer 11 and does not include an adhesive (glue layer). For example, an olefin-based sheet, a styrene-based sheet, a polyester-based sheet, or the like is used as the thermocompression bonding sheet. As examples of the olefin-based sheet, polyethylene sheet, polypropylene sheet, and so forth are cited. As examples of the styrene-based sheet, a polystyrene sheet, and so forth are cited. As examples of the polyester-based sheet, a polyethylene terephthalate sheet, a polyethylene naphthalate sheet, and so forth are cited.

The thermocompression bonding sheet is disposed on the side of the front surface 11a of the wafer 11. Then, for example, a roller internally including a heat source (heat roller) is pressed against the thermocompression bonding sheet in the state in which the roller is heated at a predetermined temperature. This causes the thermocompression bonding sheet to be pressed against the side of the front surface 11a of the wafer 11 while being heated. As a result, the thermocompression bonding sheet softens and gets deformed along the shape of the side of the front surface 11a of the wafer 11 to get close contact with the side of the front surface 11a of the wafer 11. In this manner, the thermocompression bonding sheet is thermocompression-bonded to the side of the front surface 11a of the wafer 11 and is fixed.

The thermocompression bonding sheet is heated in such a manner that a temperature of the thermocompression bonding sheet becomes at least a softening point of the thermocompression bonding sheet and at most the melting point of the thermocompression bonding sheet. However, the thermocompression bonding sheet sometimes does not have a clear softening point. In this case, the thermocompression bonding sheet is heated in such a manner that the temperature of the thermocompression bonding sheet becomes at least a temperature lower than the melting point of the thermocompression bonding sheet by a predetermined temperature (for example, 20° C.) and at most the melting point of the thermocompression bonding sheet. For example, the heating temperature can be set to at least 120° and at most 140° C. when the thermocompression bonding sheet is a polyethylene sheet, and the heating temperature can be set to at least 160° and at most 180° C. when the thermocompression bonding sheet is a polypropylene sheet. Furthermore, the heating temperature can be set to at least 220° and at most 240° C. when the thermocompression bonding sheet is a polystyrene sheet. Moreover, the heating temperature can be set to at least 250° and at most 270° C. when the thermocompression bonding sheet is a polyethylene terephthalate sheet, and the heating temperature can be set to at least 160° and at most 180° C. when the thermocompression bonding sheet is a polyethylene naphthalate sheet.

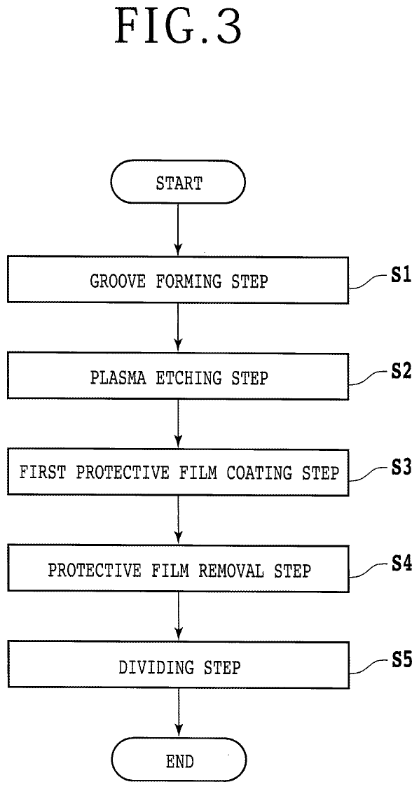

Next, a specific example of the method for dividing the wafer 11 to manufacture chips will be described. FIG. 3 is a flowchart illustrating the manufacturing method of chips.

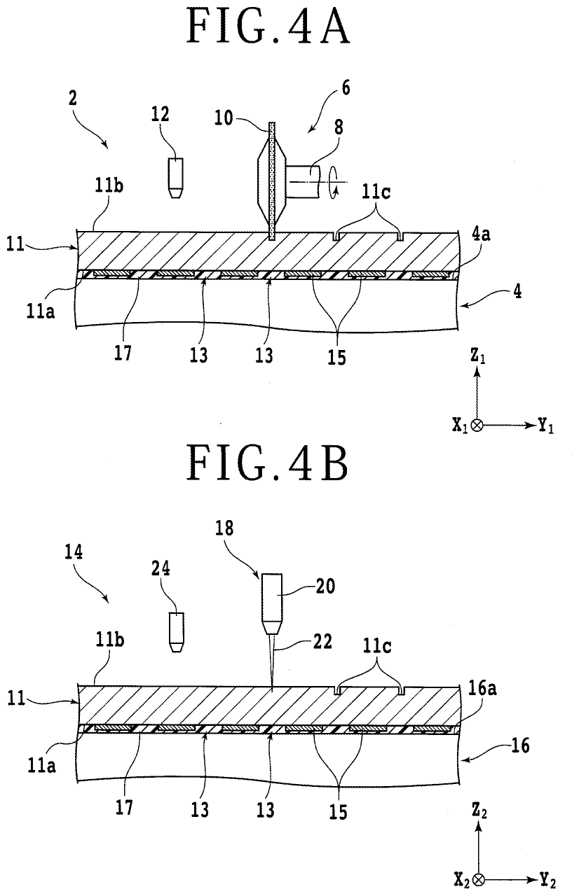

In dividing the wafer 11, first, grooves are formed along the planned dividing lines 13 on a first surface side of the wafer 11 (groove forming step S1). The wafer 11 in the groove forming step S1 is illustrated in FIG. 4A and FIG. 4B. For example, in the groove forming step S1, grooves 11c are formed on the first surface side of the wafer 11 by using a cutting apparatus 2 or a laser processing apparatus 14. In the following, the surface in which the grooves 11c are formed in the wafer 11 will be referred to as a first surface and the surface on the opposite side of the first surface will be referred to as a second surface in some cases. Specifically, when the grooves 11c are formed on the side of the back surface 11b of the wafer 11, the back surface 11b is equivalent to the first surface and the front surface 11a is equivalent to the second surface. On the other hand, when the grooves 11c are formed on the side of the front surface 11a of the wafer 11, the front surface 11a is equivalent to the first surface and the back surface 11b is equivalent to the second surface.

FIG. 4A is a partially sectional front view illustrating the wafer 11 in which the grooves 11c are formed by the cutting apparatus 2. In FIG. 4A, an X₁-axis direction (processing feed direction, first horizontal direction) and a Y₁-axis direction (indexing feed direction, second horizontal direction) are directions perpendicular to each other. Furthermore, a Z₁-axis direction (vertical direction, height direction, upward-downward direction) is the direction perpendicular to the X₁-axis direction and the Y₁-axis direction.

The cutting apparatus 2 includes a holding table (chuck table) 4 that holds the wafer 11. The upper surface of the holding table 4 is a flat surface substantially parallel to the horizontal plane (X₁Y₁-plane) and configures a circular holding surface 4a that holds the wafer 11. The holding surface 4a is connected to a suction source (not illustrated) such as an ejector through a flow path (not illustrated) formed inside the holding table 4, a valve (not illustrated), and so forth. A movement mechanism (not illustrated) of a ball screw system and a rotational drive source (not illustrated) such as a motor are coupled to the holding table 4. The movement mechanism moves the holding table 4 along the X₁-axis direction. Moreover, the rotational drive source rotates the holding table 4 around a rotation axis substantially parallel to the Z₁-axis direction.

Furthermore, the cutting apparatus 2 includes a cutting unit 6 that cuts the wafer 11. The cutting unit 6 is disposed over the holding table 4 and includes a circular columnar spindle 8 disposed along the Y₁-axis direction. An annular cutting blade 10 is mounted on a tip part (one end part) of the spindle 8. Moreover, a rotational drive source (not illustrated) such as a motor is coupled to a base end part (the other end part) of the spindle 8. The cutting blade 10 rotates around a rotation axis substantially parallel to the Y₁-axis direction by power transmitted from the rotational drive source through the spindle 8. As the cutting blade 10, for example, a cutting blade of a hub type (hub blade) is used. The hub blade includes an annular hub base composed of metal or the like and an annular cutting edge formed along the outer circumferential edge of the hub base. The cutting edge of the hub blade is configured by an electroformed abrasive stone containing abrasive grains composed of diamond or the like and a bond such as a nickel plating layer that fixes the abrasive grains. However, it is also possible to use a cutting blade of a washer type (washer blade) as the cutting blade 10. The washer blade is configured by only an annular cutting edge containing abrasive grains composed of diamond or the like and a bond that is composed of metal, ceramic, resin, or the like and fixes the abrasive grains.

A movement mechanism (not illustrated) of a ball screw system that moves the cutting unit 6 along the Y₁-axis direction and the Z₁-axis direction is coupled to the cutting unit 6. The position of the cutting blade 10 in the indexing feed direction, the depth of cutting of the cutting blade 10 into the wafer 11, and so forth are adjusted by the movement mechanism.

Moreover, the cutting apparatus 2 includes an imaging unit 12. The imaging unit 12 includes an image sensor such as a charge-coupled device (CCD) sensor or a complementary metal-oxide-semiconductor (CMOS) sensor and images the wafer 11 held by the holding table 4. For example, the imaging unit 12 is an infrared camera including an imaging element that receives infrared light and converts it to an electrical signal. Furthermore, the imaging unit 12 images a pattern (device 15 or the like) formed on the side of the front surface 11a of the wafer 11 through the wafer 11. Based on a pattern image acquired by the imaging unit 12, the positions of the planned dividing lines 13 are identified, and position adjustment between the wafer 11 and the cutting blade 10 is executed.

When the wafer 11 is cut by the cutting apparatus 2, first, the wafer 11 is held by the holding table 4. For example, in the case of cutting the side of the back surface 11b of the wafer 11, the wafer 11 is disposed over the holding table 4 in such a manner that the side of the back surface 11b is oriented upward and the side of the front surface 11a (side of the protective sheet 17) faces the holding surface 4a. When a suction force (negative pressure) of the suction source is caused to act on the holding surface 4a in this state, the wafer 11 is held under suction by the holding table 4 with the interposition of the protective sheet 17.

Next, the holding table 4 is rotated to align the length direction of the predetermined planned dividing line 13 with the X₁-axis direction. Moreover, the position of the cutting unit 6 in the Y₁-axis direction is adjusted to cause the cutting blade 10 to overlap with an extended line of the predetermined planned dividing line 13. In addition, the height (position in the Z₁-axis direction) of the cutting unit 6 is adjusted to cause the lower end of the cutting blade 10 to be disposed on the lower side relative to the back surface 11b and on the upper side relative to the front surface 11a. Then, the holding table 4 is moved along the X₁-axis direction while the cutting blade 10 is rotated. This causes the holding table 4 and the cutting blade 10 to move relative to each other along the X₁-axis direction, and the cutting blade 10 cuts into the side of the back surface 11b of the wafer 11 along the planned dividing line 13. As a result, the groove 11c (cut groove) having a depth smaller than the thickness of the wafer 11 is formed along the planned dividing line 13 on the side of the back surface 11b of the wafer 11. Thereafter, by repeating a similar procedure, the wafer 11 is cut along all planned dividing lines 13, and multiple grooves 11c are formed in a lattice manner.

FIG. 4B is a partially sectional front view illustrating the wafer 11 in which the grooves 11c are formed by the laser processing apparatus 14. In the groove forming step S1, it is also possible to form the grooves 11c in the wafer 11 by using the laser processing apparatus 14 instead of the cutting apparatus 2. In FIG. 4B, an X₂-axis direction (processing feed direction, first horizontal direction) and a Y₂-axis direction (indexing feed direction, second horizontal direction) are directions perpendicular to each other. Furthermore, a Z₂-axis direction (vertical direction, height direction, upward-downward direction) is the direction perpendicular to the X₂-axis direction and the Y₂-axis direction.

The laser processing apparatus 14 includes a holding table (chuck table) 16 that holds the wafer 11. The holding table 16 includes a holding surface 16a that holds the wafer 11. The configuration and functions of the holding table 16 are similar to those of the holding table 4 (see FIG. 4A) of the cutting apparatus 2. A movement mechanism (not illustrated) of a ball screw system and a rotational drive source (not illustrated) such as a motor are coupled to the holding table 16. The movement mechanism moves the holding table 16 along the X₂-axis direction and the Y₂-axis direction. Moreover, the rotational drive source rotates the holding table 16 around a rotation axis substantially parallel to the Z₂-axis direction.

Furthermore, the laser processing apparatus 14 includes a laser irradiation unit 18 that executes irradiation with a laser beam. The laser irradiation unit 18 includes a laser oscillator (not illustrated) of a yttrium aluminum garnet (YAG) laser, yttrium vanadate (YVO₄) laser, yttrium lithium fluoride (YLF) laser, or the like and a laser processing head 20 disposed over the holding table 16. In the laser processing head 20, an optical system (not illustrated) that guides the laser beam of pulse oscillation emitted from the laser oscillator to the wafer 11 is housed. The optical system is configured to include optical elements such as collecting lens and mirror. Laser processing is executed for the wafer 11 through irradiation of the wafer 11 with a laser beam 22 from the laser irradiation unit 18.

Moreover, the laser processing apparatus 14 includes an imaging unit 24. The configuration and functions of the imaging unit 24 are similar to those of the imaging unit 12 (see FIG. 4A) of the cutting apparatus 2. Based on a pattern image acquired by the imaging unit 24, the positions of the planned dividing lines 13 are identified and position adjustment between the wafer 11 and the laser beam 22 is executed.

When the wafer 11 is processed by the laser processing apparatus 14, first, the wafer 11 is held by the holding table 16. For example, in the case of executing laser processing for the side of the back surface 11b of the wafer 11, the wafer 11 is disposed over the holding table 16 in such a manner that the side of the back surface 11b is oriented upward and the side of the front surface 11a (side of the protective sheet 17) faces the holding surface 16a. When a suction force (negative pressure) of a suction source is caused to act on the holding surface 16a in this state, the wafer 11 is held under suction by the holding table 16 with the interposition of the protective sheet 17.

Next, the holding table 16 is rotated to align the length direction of the predetermined planned dividing line 13 with the X₂-axis direction. Furthermore, the position of the holding table 16 in the Y₂-axis direction is adjusted in such a manner that a region to be irradiated with the laser beam 22 overlaps with an extended line of the predetermined planned dividing line 13. Moreover, the position of the laser processing head 20 and the arrangement of the optical elements included in the optical system are adjusted to cause the focal point of the laser beam 22 to be positioned to the same height (position in the Z₂-axis direction) as the front surface 11a or the inside of the wafer 11. Then, the holding table 16 is moved along the X₂-axis direction while irradiation with the laser beam 22 from the laser processing head 20 is executed. This causes the holding table 16 and the laser beam 22 to move relative to each other along the X₂-axis direction, and the side of the back surface 11b of the wafer 11 is irradiated with the laser beam 22 along the planned dividing line 13.

For example, an irradiation condition of the laser beam 22 is set to cause ablation processing to be executed for the wafer 11. Specifically, the wavelength of the laser beam 22 is set to cause at least part of the laser beam 22 to be absorbed by the wafer 11. That is, the laser beam 22 is a laser beam having absorbability with respect to the wafer 11. Furthermore, other irradiation conditions of the laser beam 22 are also set as appropriate to cause the ablation processing to be properly executed for the wafer 11. For example, when the wafer 11 is a single-crystal silicon wafer, irradiation conditions of the laser beam 22 can be set as follows.

Wavelength: 355 nm

Average output power: 2 W

Repetition frequency: 200 kHz

Processing feed rate: 400 mm/s

When the wafer 11 is irradiated with the laser beam 22 along the planned dividing line 13, the region irradiated with the laser beam 22 in the wafer 11 is removed by ablation. As a result, the groove 11c (laser-processed groove) having a depth smaller than the thickness of the wafer 11 is formed along the planned dividing line 13 on the side of the back surface 11b of the wafer 11. Thereafter, by repeating a similar procedure, the wafer 11 is processed along all planned dividing lines 13, and multiple grooves 11c are formed in a lattice manner. When it is difficult to form the groove 11c with a desired depth in the wafer 11 by one time of scanning with the laser beam 22, irradiation with the laser beam 22 may be executed multiple times along each planned dividing line 13.

By processing the wafer 11 by the processing apparatus as above, the grooves 11c in a lattice manner are formed along the planned dividing lines 13 on the side of the back surface 11b of the wafer 11. The dimensions of the grooves 11c are set as appropriate to cause the wafer 11 to be properly divided in a dividing step S5 to be described later. Specifically, the width of the grooves 11c can be set equal to or smaller than 100 μm, preferably equal to or smaller than 50 μm, more preferably equal to or smaller than 20 μm. For example, the grooves 11c whose width is at least 15 μm and at most 20 μm may be formed by using the cutting apparatus 2 (see FIG. 4A), or the grooves 11c whose width is equal to or smaller than 10 μm may be formed by using the laser processing apparatus 14 (see FIG. 4B). Moreover, for example, the grooves 11c are formed in such a manner that an aspect ratio B/A of a width A of the grooves 11c and a depth B of the grooves 11c becomes equal to or higher than 1, preferably equal to or higher than 2, in the groove forming step S1.

Next, plasma etching is executed for the wafer 11 from the first surface side in the state in which the grooves 11c are exposed (plasma etching step S2). In the plasma etching step S2, for example, a plasma treatment apparatus is used.

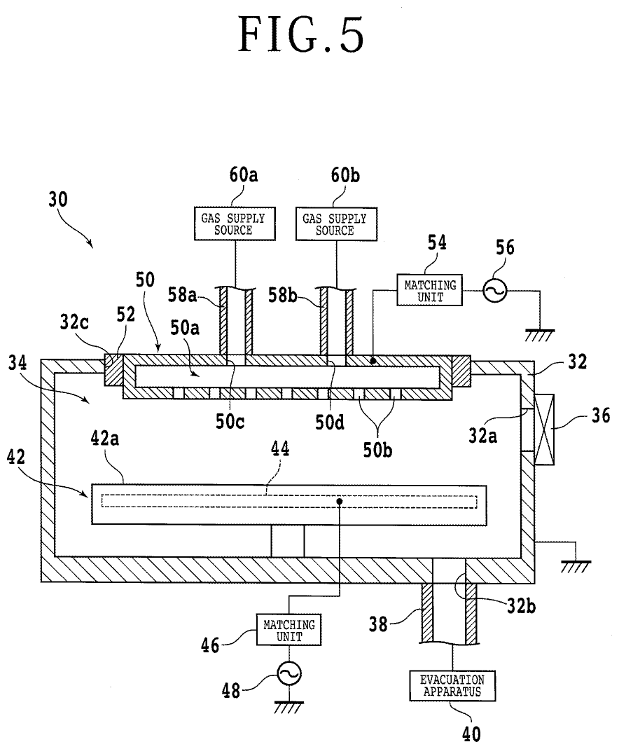

FIG. 5 is a partially sectional front view illustrating a plasma treatment apparatus 30. The plasma treatment apparatus 30 includes a chamber 32 in which the wafer 11 is housed. The chamber 32 is composed of an electrically-conductive material such as metal and is grounded. The inside of the chamber 32 is equivalent to a treatment space 34 in which plasma treatment for the wafer 11 is executed.

An opening 32a for conveyance of the wafer 11 is made in a sidewall of the chamber 32. A gate (opening-closing door) 36 that opens and closes the opening 32a is disposed outside the opening 32a. A movement mechanism (not illustrated) such as an air cylinder is coupled to the gate 36, and the movement mechanism raises and lowers the gate 36 along the sidewall of the chamber 32. Lowering the gate 36 to expose the opening 32a makes it possible to carry in the wafer 11 to the treatment space 34 through the opening 32a or carry out the wafer 11 from the treatment space 34 through the opening 32a. Furthermore, the treatment space 34 is sealed by raising the gate 36 to close the opening 32a.

An opening 32b that connects the inside and outside of the chamber 32 is made in the bottom wall of the chamber 32. The opening 32b is connected to evacuation apparatus 40 such as a vacuum pump through a pipe 38. When the evacuation apparatus 40 is actuated in the state in which the treatment space 34 is sealed, the treatment space 34 is subjected to evacuation and pressure reduction.

A holding table (chuck table) 42 that holds the wafer 11 is disposed in the treatment space 34. The upper surface of the holding table 42 is a flat surface substantially parallel to the horizontal plane and configures a holding surface 42a that holds the wafer 11. An electrostatic chuck that holds the wafer 11 by an electrical force can be used as the holding table 42. For example, the holding table 42 is composed of a dielectric such as ceramic, and an electrode 44 with a circular disc shape is disposed inside the holding table 42. The electrode 44 is disposed substantially in parallel to the holding surface 42a and is connected to a high-frequency power supply 48 through a matching unit 46. A cooling path (not illustrated) in which a cooling liquid such as water flows may be made inside the holding table 42. The holding table 42 is cooled by causing the cooling liquid to flow in the cooling path.

A gas ejection head 50 is disposed above the holding table 42. The gas ejection head 50 is composed of an electrically-conductive material such as metal and is inserted in an opening 32c made in the top wall of the chamber 32. An annular bearing 52 composed of an insulating material is disposed between the chamber 32 and the gas ejection head 50. The bearing 52 is disposed to surround the gas ejection head 50 and insulates the chamber 32 from the gas ejection head 50.

The gas ejection head 50 is connected to a high-frequency power supply 56 through a matching unit 54. Moreover, a raising-lowering mechanism (not illustrated) that raises and lowers the gas ejection head 50 along the vertical direction is coupled to the gas ejection head 50. The interval between the holding table 42 and the gas ejection head 50 is adjusted by raising and lowering the gas ejection head 50 by the raising-lowering mechanism.

A gas diffusion space 50a to which a gas for plasma treatment is supplied is made inside the gas ejection head 50. Furthermore, multiple gas supply paths 50b that couple the treatment space 34 of the chamber 32 and the gas diffusion space 50a are made on the lower surface side of the gas ejection head 50. Moreover, a pair of gas supply paths 50c and 50d are made on the upper surface side of the gas ejection head 50. The gas supply path 50c is connected to a gas supply source 60a through a pipe 58a. The gas supply path 50d is connected to a gas supply source 60b through a pipe 58b. The gas supply source 60a supplies a gas for plasma treatment to the gas diffusion space 50a through the pipe 58a and the gas supply path 50c. Similarly, the gas supply source 60b supplies a gas for plasma treatment to the gas diffusion space 50a through the pipe 58b and the gas supply path 50d. This causes the two kinds of gas to be mixed in the gas diffusion space 50a. Although the form in which the gas is supplied from the two gas supply sources 60a and 60b to the gas ejection head 50 is illustrated in FIG. 5, the number of gas supply sources connected to the gas ejection head 50 may be one or may be three or more.

When plasma treatment is executed for the wafer 11 by using the plasma treatment apparatus 30, first, the gate 36 lowers and the opening 32a is exposed. Then, the wafer 11 is carried in to the treatment space 34 through the opening 32a by a conveying mechanism (not illustrated) and is disposed over the holding surface 42a of the holding table 42. It is preferable to raise the gas ejection head 50 and widen the interval between the holding table 42 and the gas ejection head 50 at the time of the carrying-in of the wafer 11.

Next, the gate 36 rises and the opening 32a is closed, so that the treatment space 34 is sealed. Then, a predetermined voltage is applied to the electrode 44 by the high-frequency power supply 48. This causes dielectric polarization on the side of the holding surface 42a of the holding table 42, and an electrostatic attraction force acts between the holding surface 42a and the wafer 11. As a result, the wafer 11 is attracted and held by the holding surface 42a. Furthermore, the height of the gas ejection head 50 is adjusted to cause the holding table 42 and the gas ejection head 50 to be disposed at an interval suitable for the plasma treatment. Moreover, the evacuation apparatus 40 operates and the pressure of the treatment space 34 is reduced.

Next, the gas for plasma treatment is supplied from the gas supply source 60a and/or the gas supply source 60b to the gas diffusion space 50a. Furthermore, a high-frequency voltage is applied to the gas ejection head 50 by the high-frequency power supply 56. As a result, the gas in the gas diffusion space 50a is turned into plasma, and the gas in the plasma state is supplied to the treatment space 34 through the multiple gas supply paths 50b and is dispersed therein. Due to this, the gas in the plasma state is supplied to the wafer 11 over the holding table 42, and predetermined plasma treatment (film deposition treatment, etching treatment, or the like) is executed for the wafer 11.

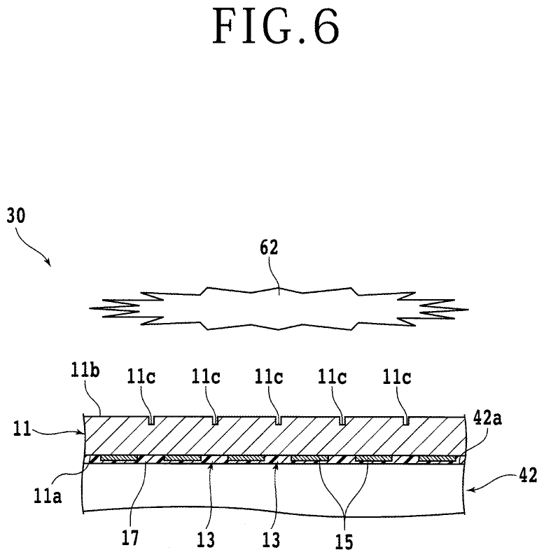

In the plasma etching step S2, the grooves 11c formed in the wafer 11 are repaired by executing plasma etching for the wafer 11 with use of the plasma treatment apparatus 30. FIG. 6 is a partially sectional front view illustrating the wafer 11 in the plasma etching step S2.

The wafer 11 is held by the holding table 42 in such a manner that the side of the back surface 11b in which the grooves 11c are formed (first surface side) is exposed upward and the side of the front surface 11a (side of the protective sheet 17, second surface side) faces the holding surface 42a. Moreover, a gas for etching is supplied to the gas diffusion space 50a (see FIG. 5) of the gas ejection head 50. In addition, a high-frequency voltage is applied to the gas ejection head 50. This causes the gas in the gas diffusion space 50a to be turned into plasma, and an etching gas in the plasma state containing ions and radicals is generated. For example, when the wafer 11 is a single-crystal silicon wafer, a fluorine-based gas (CF₄, SF₆, or the like) supplied from the gas supply source 60a and an inert gas (He, Ar, or the like) supplied from the gas supply source 60b are mixed in the gas diffusion space 50a. Then, the mixed gas is turned into plasma, and a gas 62 (see FIG. 6) in the plasma state is supplied to the side of the back surface 11b of the wafer 11. As a result, plasma etching is executed for the wafer 11 from the side of the back surface 11b. At this time, part of the gas 62 enters the grooves 11c and acts on the side surfaces and bottom surfaces of the grooves 11c, and plasma etching is executed for the side surfaces and bottom surfaces of the grooves 11c.

When the above-described groove forming step S1 (see FIG. 4A and FIG. 4B) is executed, processing marks such as minute recesses and projections often remain in the side surfaces and bottom surfaces of the grooves 11c. However, the processing marks remaining in the side surfaces and bottom surfaces of the grooves 11c are removed by executing the plasma etching for the inside of the grooves 11c as above. This suppresses the lowering of the strength of chips obtained through dividing of the wafer 11.

The plasma etching executed for the wafer 11 in the plasma etching step S2 may be isotropic plasma etching or may be anisotropic plasma etching. The kind of plasma etching is selected as appropriate according to the material of the wafer 11, the shape and dimensions of the grooves 11c, and so forth. In the case of executing isotropic plasma etching for the wafer 11, a high-frequency voltage is applied to the gas ejection head 50 (see FIG. 5) in the state in which a high-frequency voltage is not applied to the electrode 44 (see FIG. 5). This causes the gas 62 in the plasma state generated in the gas ejection head 50 to be evenly dispersed in the treatment space 34, and the wafer 11 is isotropically etched. On the other hand, in the case of executing anisotropic plasma etching for the wafer 11, a high-frequency voltage is applied to the gas ejection head 50 in the state in which a high-frequency voltage is applied to the electrode 44. This causes the gas 62 in the plasma state generated in the gas ejection head 50 to accelerate toward the holding table 42 and the wafer 11 is anisotropically etched along the thickness direction of the wafer 11.

When repair of the grooves 11c is unnecessary, the plasma etching step S2 does not need to be executed. For example, the plasma etching step S2 can be omitted when the wafer 11 is processed with processing conditions under which processing marks are less liable to be formed in the groove forming step S1 or when remaining of processing marks does not affect the quality of chips.

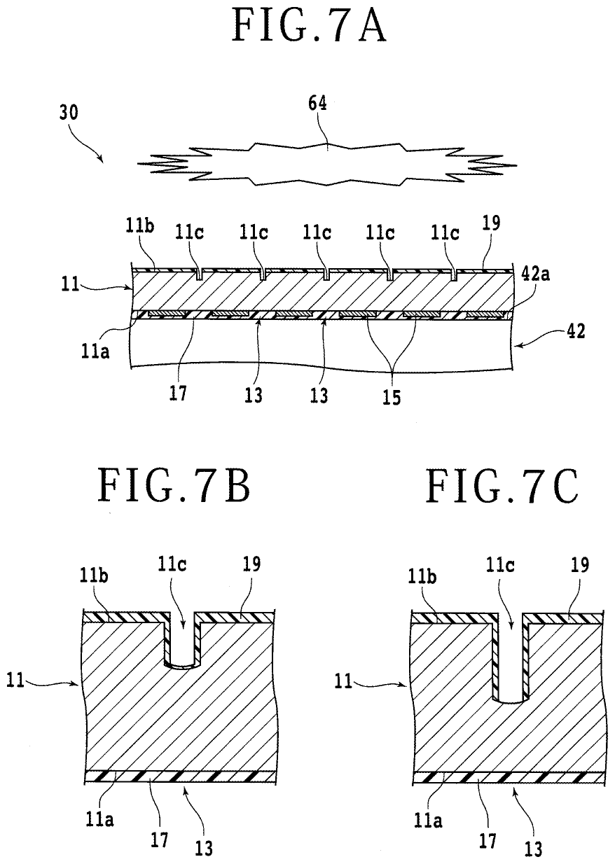

Next, the first surface of the wafer 11 and the side surfaces of the grooves 11c are coated with a first protective film (first protective film coating step S3). FIG. 7A is a partially sectional front view illustrating the wafer 11 in the first protective film coating step S3.

For example, in the first protective film coating step S3, a first protective film 19 is formed by using the plasma treatment apparatus 30 illustrated in FIG. 5. Specifically, first, the wafer 11 is held by the holding table 42 in such a manner that the side of the back surface 11b in which the grooves 11c are formed (first surface side) is exposed upward and the side of the front surface 11a (side of the protective sheet 17, second surface side) faces the holding surface 42a. Furthermore, a gas for protective film formation is supplied to the gas diffusion space 50a of the gas ejection head 50. In addition, a high-frequency voltage is applied to the gas ejection head 50. This causes the gas in the gas diffusion space 50a to be turned into plasma, and the gas for film deposition in the plasma state containing ions and radicals is generated. Then, a gas 64 (see FIG. 7A) in the plasma state is supplied to the side of the back surface 11b of the wafer 11 and the ions and radicals contained in the gas 64 are deposited on the side of the back surface 11b of the wafer 11. This forms the first protective film 19 on the side of the back surface 11b of the wafer 11. For example, a gas containing C₄F₈ is supplied from the gas supply source 60a and an Ar gas is supplied from the gas supply source 60b. In this case, CF radicals contained in the gas 64 are deposited on the side of the back surface 11b of the wafer 11 and the insulating first protective film 19 containing carbon fluoride is formed on the side of the back surface 11b of the wafer 11.

FIG. 7B is a sectional view illustrating part of the wafer 11 in which the side surfaces and bottom surfaces of the grooves 11c are coated with the first protective film 19. When the first protective film 19 is formed, the ions and radicals contained in the gas 64 enter the grooves 11c and are deposited also on the side surfaces and bottom surfaces of the grooves 11c in addition to being deposited on the side of the back surface 11b of the wafer 11. As a result, the back surface 11b of the wafer 11 and the side surfaces and bottom surfaces of the grooves 11c are coated with the first protective film 19. However, the inside of the groove 11c is less liable to be supplied with the gas 64 compared with the back surface 11b of the wafer 11. Moreover, a region closer to the bottom surface of the groove 11c is less liable to be supplied with the gas 64. Thus, the first protective film 19 formed inside the grooves 11c is thinner than the first protective film 19 formed on the side of the back surface 11b of the wafer 11. Furthermore, the first protective film 19 formed on the bottom surfaces of the grooves 11c is thinner than the first protective film 19 formed on the side surfaces of the grooves 11c. In particular, when the aspect ratio B/A of the width A of the grooves 11c and the depth B of the grooves 11c is equal to or higher than 1 (preferably equal to or higher than 2), ions and radicals are less liable to be deposited on the bottom surfaces of the grooves 11c and the first protective film 19 that is thin is formed on the bottom surfaces of the grooves 11c.

Moreover, it has been confirmed that, when the gas 64 is supplied to the wafer 11 under low temperature, the ions and radicals contained in the gas 64 are deposited mainly on the back surface 11b of the wafer 11 and become less likely to enter the grooves 11c. Thus, it is preferable to deposit the first protective film 19 under a low-temperature environment in the case of forming the part that coats the inside of the grooves 11c in the first protective film 19 more thinly than the part that coats the back surface 11b of the wafer 11. For example, while deposition of the first protective film 19 is executed, the temperature of the treatment space 34 (see FIG. 5) of the chamber 32 is kept equal to or lower than 0° C., preferably equal to or lower than −10° C., more preferably equal to or lower than −20° C. Alternatively, while deposition of the first protective film 19 is executed, the temperature of the wafer 11 is kept equal to or lower than 0° C., preferably equal to or lower than −10° C., more preferably equal to or lower than −20° C.

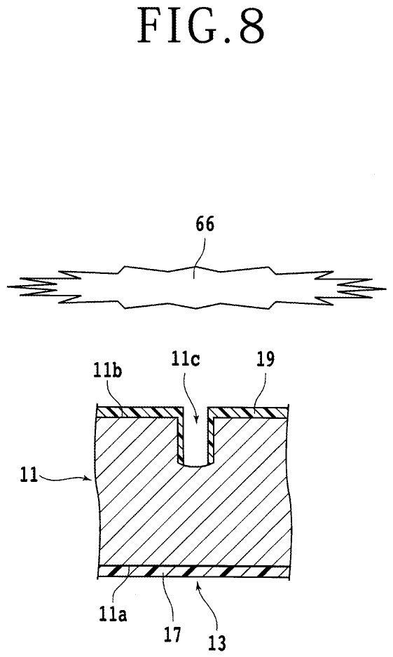

After the first protective film coating step S3, the parts that coat the bottom surfaces of the grooves 11c in the first protective film 19 may be removed to expose the bottom surfaces of the grooves 11c by executing plasma etching for the wafer 11 from the first surface side (protective film removal step S4). FIG. 8 is a sectional view illustrating part of the wafer 11 in the protective film removal step S4.

In the protective film removal step S4, plasma etching is executed for the side of the back surface 11b of the wafer 11 in a procedure similar to that of the above-described plasma etching step S2 (see FIG. 6). Specifically, a gas 66 turned into plasma in the gas diffusion space 50a (see FIG. 5) of the gas ejection head 50 is supplied to the side of the back surface 11b of the wafer 11 and isotropic or anisotropic plasma etching is executed for the wafer 11. This causes the first protective film 19 to be thinned. The first protective film 19 is formed in such a manner that the parts that coat the bottom surfaces of the grooves 11c are the thinnest. Furthermore, in the protective film removal step S4, the etching is continued until the parts deposited on the bottom surfaces of the grooves 11c in the first protective film 19 are removed. As a result, the bottom surfaces of the grooves 11c are exposed with the back surface 11b of the wafer 11 and the side surfaces of the grooves 11c remaining coated with the first protective film 19.

However, when the aspect ratio B/A of the width A of the grooves 11c and the depth B of the grooves 11c is high, the gas 64 is particularly less liable to be supplied to the bottom surfaces of the grooves 11c in the first protective film coating step S3 (see FIG. 7A). Thus, at the timing when the first protective film coating step S3 is completed, the first protective film 19 is not formed on the bottom surfaces of the grooves 11c and the bottom surfaces of the grooves 11c are exposed in some cases. FIG. 7C is a sectional view illustrating part of the wafer 11 in which the side surfaces of the grooves 11c are coated with the first protective film 19. The protective film removal step S4 can be omitted when the bottom surfaces of the grooves 11c are already exposed at the timing when the first protective film coating step S3 is completed as illustrated in FIG. 7C. Moreover, even when the bottom surfaces of the grooves 11c are covered by the first protective film 19 at the timing when the first protective film coating step S3 is completed, the protective film removal step S4 may be omitted when the thickness of the parts that coat the bottom surfaces of the grooves 11c in the first protective film 19 is equal to or smaller than a predetermined value (for example, equal to or smaller than 10 nm).

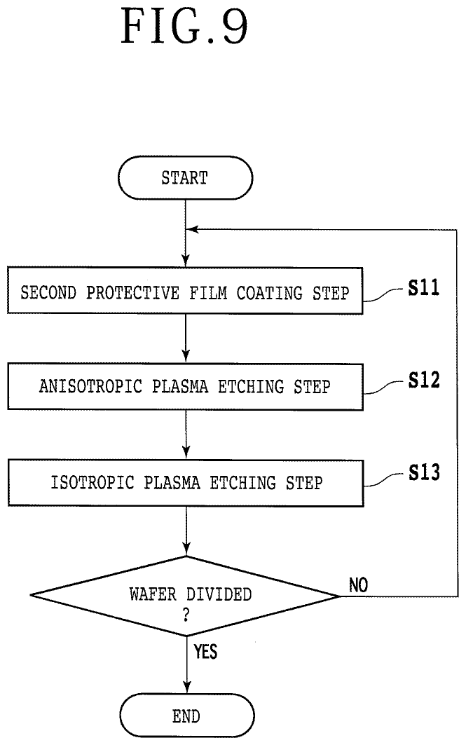

Next, the wafer 11 is divided along the planned dividing lines 13 (dividing step S5). In the dividing step S5, plasma etching is executed for the wafer 11 from the first surface side. FIG. 9 is a flowchart illustrating an example of the dividing step S5.

For example, in the dividing step S5, the wafer 11 is divided by extending the grooves 11c to the second surface (front surface 11a) of the wafer 11 by use of the Bosch process. Specifically, the grooves 11c are caused to reach the front surface 11a of the wafer 11 by sequentially executing a second protective film coating step S11, an anisotropic plasma etching step S12, and an isotropic plasma etching step S13 to repeat work of etching the bottom surfaces of the grooves 11c. The plasma treatment apparatus 30 illustrated in FIG. 5 can be used for the plasma etching.

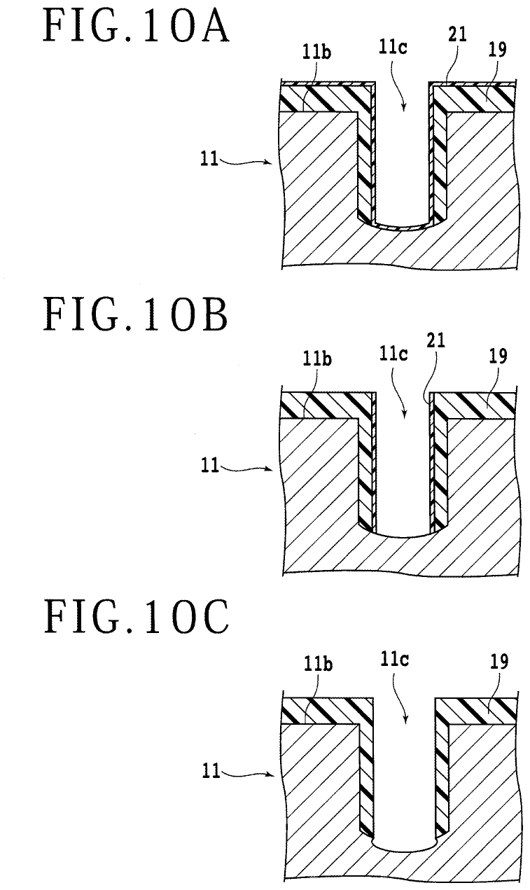

FIG. 10A is a sectional view illustrating part of the wafer 11 in the second protective film coating step S11. In the second protective film coating step S11, the side surfaces and bottom surfaces of the grooves 11c are coated with a second protective film 21 thinner than the first protective film 19. Specifically, first, the wafer 11 is held by the holding table 42 (see FIG. 5) in such a manner that the side of the back surface 11b (first surface side) is exposed upward and the side of the front surface 11a (second surface side) faces the holding surface 42a. Furthermore, a gas for protective film formation is supplied to the gas diffusion space 50a (see FIG. 5) of the gas ejection head 50. In addition, a high-frequency voltage is applied to the gas ejection head 50. As a result, the gas for film deposition in the plasma state is supplied to the side of the back surface 11b of the wafer 11 and the second protective film 21 is formed on the side of the back surface 11b of the wafer 11 and inside the grooves 11c.

The specific forming method of the second protective film 21 is similar to the forming method of the first protective film 19 (see FIG. 7A). However, the thickness of the second protective film 21 is set smaller than that of the first protective film 19. For example, a mixed gas of a gas containing C₄F₈ and an Ar gas is turned into plasma and is supplied to the side of the back surface 11b of the wafer 11 for a certain period of time (for example, at least six seconds and at most eight seconds). This causes the insulating second protective film 21 containing carbon fluoride to be formed with a predetermined thickness (for example, equal to or smaller than 10 nm). As a result, as illustrated in FIG. 10A, the back surface 11b and the side surfaces of the grooves 11c (upper surface and side surfaces of the first protective film 19) of the wafer 11 and the exposed bottom surfaces of the grooves 11c are coated with the second protective film 21 thinner than the first protective film 19.

FIG. 10B is a sectional view illustrating part of the wafer 11 in the anisotropic plasma etching step S12. In the anisotropic plasma etching step S12, the bottom surfaces of the grooves 11c are exposed by executing anisotropic plasma etching from the first surface side (side of the back surface 11b) for the wafer 11 over which the second protective film 21 is formed. Specifically, a gas for etching is supplied to the gas diffusion space 50a (see FIG. 5) of the gas ejection head 50. For example, when the wafer 11 is a single-crystal silicon wafer, a fluorine-based gas (CF₄, SF₆, or the like) is supplied from the gas supply source 60a and an inert gas (He, Ar, or the like) is supplied from the gas supply source 60b. Then, a high-frequency voltage is applied to each of the electrode 44 (see FIG. 5) and the gas ejection head 50. This causes the gas in the gas diffusion space 50a to be turned into plasma and be accelerated toward the holding table 42, and anisotropic plasma etching is executed for the wafer 11. When the anisotropic plasma etching is continued for a certain period of time (for example, approximately three seconds), with the parts that cover the side surfaces of the grooves 11c (side surfaces of the first protective film 19) in the second protective film 21 remaining, the parts that cover the bottom surfaces of the grooves 11c in the second protective film 21 are removed and the bottom surfaces of the grooves 11c are exposed.

FIG. 10C is a sectional view illustrating part of the wafer 11 in the isotropic plasma etching step S13. In the isotropic plasma etching step S13, the bottom surfaces of the grooves 11c are etched by executing isotropic plasma etching from the first surface side (side of the back surface 11b) for the wafer 11 for which the anisotropic plasma etching has been executed. Specifically, a gas for etching is supplied to the gas diffusion space 50a (see FIG. 5) of the gas ejection head 50. Examples of the gas for etching are similar to those of the anisotropic plasma etching step S12. Then, a high-frequency voltage is applied to the gas ejection head 50. As a result, the gas supplied to the gas diffusion space 50a is turned into plasma and the gas in the plasma state is supplied to the side of the back surface 11b of the wafer 11 for a certain period of time (for example, at least five seconds and at most seven seconds). A high-frequency voltage is not applied to the electrode 44 (see FIG. 5). Thus, isotropic plasma etching is executed for the wafer 11. As a result, the bottom surfaces of the grooves 11c and the vicinities thereof are removed and the grooves 11c are extended toward the side of the front surface 11a of the wafer 11. Moreover, part or the whole of the second protective film 21 that coats the side surfaces of the grooves 11c (side surfaces of the first protective film 19) is removed.

Thereafter, the above-described second protective film coating step S11, the anisotropic plasma etching step S12, and the isotropic plasma etching step S13 are repeated until the grooves 11c reach the front surface 11a of the wafer 11 (see FIG. 9). This causes the wafer 11 to be divided along the planned dividing lines 13.

Here, if the back surface 11b of the wafer 11 is exposed in the dividing step S5, when plasma etching is executed for the wafer 11, a large part of ions and radicals contained in the gas in the plasma state is consumed by the back surface 11b of the wafer 11 and the gas becomes less likely to enter the inside of the grooves 11c. As a result, the total supply amount of the gas necessary for etching the bottom surfaces of the grooves 11c increases. Furthermore, the etching rate lowers and the treatment time required for the etching of the bottom surfaces of the grooves 11c becomes long. On the other hand, in the present embodiment, plasma etching is executed for the wafer 11 in the state in which the back surface 11b of the wafer 11 is coated with the first protective film 19. Owing to this, ions and radicals do not act on the back surface 11b of the wafer 11 and become more likely to be supplied to the inside of the grooves 11c, and the amount of etching gas consumed in the plasma etching is reduced. Moreover, the bottom surfaces of the grooves 11c are efficiently etched and thus the etching time is shortened.

In the above-described first protective film coating step S3 (see FIG. 7A), the thickness of the first protective film 19 is adjusted to allow keeping of the state in which the side of the back surface 11b of the wafer 11 is coated with the first protective film 19 in the plasma etching in the dividing step S5. For example, when the above-described Bosch process is employed in the dividing step S5, it is preferable that the thickness of the first protective film 19 be equal to or larger than 50 times the thickness of the second protective film 21 and it is more preferable that the thickness be 100 times. Specifically, when the thickness of the second protective film 21 is equal to or smaller than 10 nm, the thickness of the first protective film 19 can be set to be equal to or larger than 500 nm, preferably equal to or larger than 1000 nm.

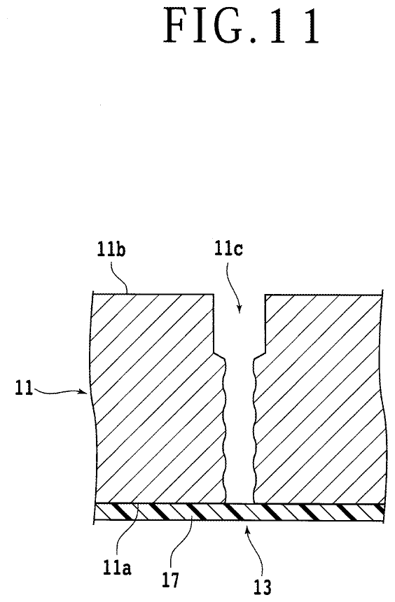

FIG. 11 is a sectional view illustrating part of the wafer 11 obtained after the dividing step S5. When the grooves 11c reach the front surface 11a of the wafer 11, the wafer 11 is divided along the planned dividing lines 13. Then, the first protective film 19 and the second protective film 21 are removed by asking treatment. This manufactures multiple chips (device chips) each including the device 15 (see FIG. 1).

As above, in the manufacturing method of chips according to the present embodiment, after the first protective film 19 is formed on the first surface side of the wafer 11 in which the grooves 11c are formed along the planned dividing lines 13, plasma etching is executed for the first surface side of the wafer 11. Owing to this, the first protective film 19 functions as a mask and the wafer 11 is selectively etched along the planned dividing lines 13. When the above-described manufacturing method of chips is used, the plasma etching is executed for the inside of the grooves 11c in the state in which the first surface side of the wafer 11 is coated with the first protective film 19. This causes the etching gas to be efficiently supplied to the grooves 11c. Therefore, the consumption amount of the etching gas is suppressed and the cost is reduced. Furthermore, the etching time is shortened and the processing efficiency of the wafer 11 improves.

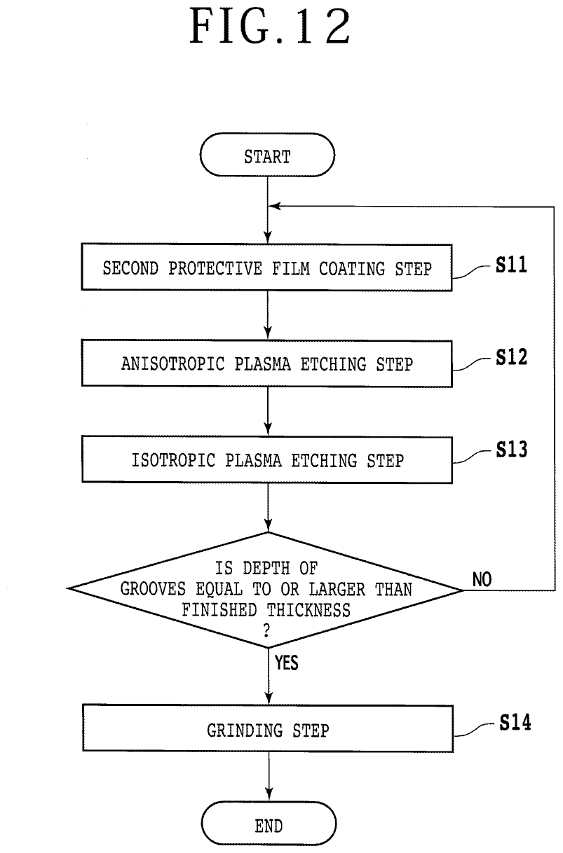

In the above-described embodiment, description has been made about the example in which the wafer 11 is divided by causing the grooves 11c formed on the side of the back surface 11b of the wafer 11 to reach the front surface 11a of the wafer 11 by plasma etching. However, the form of the dividing step S5 is not limited to the above description. FIG. 12 is a flowchart illustrating another example of the dividing step S5.

For example, in the dividing step S5, it is also possible to divide the wafer 11 by grinding the side of the back surface 11b of the wafer 11 after forming the grooves 11c on the side of the front surface 11a of the wafer 11. In this case, the front surface 11a of the wafer 11 is equivalent to the first surface and the back surface 11b of the wafer 11 is equivalent to the second surface.

Specifically, first, the groove forming step S1, the first protective film coating step S3, and the protective film removal step S4 (see FIG. 3) are executed to form the grooves 11c along the planned dividing lines 13 on the side of the front surface 11a of the wafer 11. Thereafter, plasma etching is executed for the side of the front surface 11a of the wafer 11 (second protective film coating step S11, anisotropic plasma etching step S12, and isotropic plasma etching step S13) to extend the grooves 11c toward the side of the back surface 11b of the wafer 11. The plasma etching is continued until the depth of the grooves 11c becomes smaller than the thickness of the wafer 11 but equal to or larger than a target value (finished thickness) of the final thickness of the wafer 11.

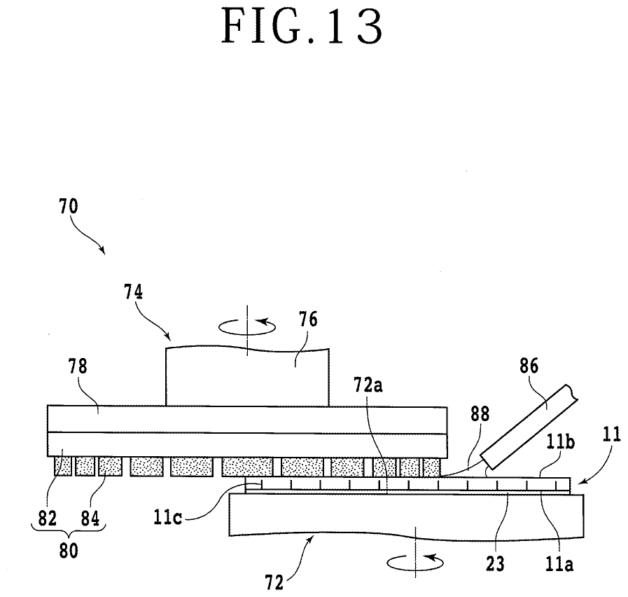

Next, the side of the back surface 11b of the wafer 11 is ground and the grooves 11c are exposed in the back surface 11b of the wafer 11 (grinding step S14). FIG. 13 is a front view illustrating the wafer 11 in the grinding step S14. For example, a grinding apparatus is used for the grinding of the wafer 11.

A grinding apparatus 70 includes a holding table (chuck table) 72 that holds the wafer 11. The upper surface of the holding table 72 is a flat surface substantially parallel to the horizontal plane and configures a holding surface 72a that holds the wafer 11. The holding surface 72a is connected to a suction source (not illustrated) such as an ejector through a flow path (not illustrated) formed inside the holding table 72, a valve (not illustrated), and so forth. A movement mechanism (not illustrated) that moves the holding table 72 along the horizontal direction is coupled to the holding table 72. As the movement mechanism, a movement mechanism of a ball screw system, a turntable that supports the holding table 72 and rotates, and so forth are used. Moreover, a rotational drive source (not illustrated) that rotates the holding table 72 around a rotation axis substantially parallel to the vertical direction is coupled to the holding table 72.

Furthermore, the grinding apparatus 70 includes a grinding unit 74 that grinds the wafer 11. The grinding unit 74 is disposed over the holding table 72 and includes a circular columnar spindle 76 disposed along the vertical direction. A circular disc-shaped mount 78 composed of metal or the like is fixed to a tip part (lower end part) of the spindle 76. Moreover, a rotational drive source (not illustrated) such as a motor that rotates the spindle 76 is connected to a base end part (upper end part) of the spindle 76.

A grinding wheel 80 that grinds the wafer 11 is mounted on the lower surface side of the mount 78. The grinding wheel 80 includes an annular wheel base 82. The wheel base 82 is composed of metal such as stainless steel or aluminum and is formed with substantially the same diameter as the mount 78. Furthermore, multiple grinding abrasive stones 84 are fixed to the lower surface side of the wheel base 82. The multiple grinding abrasive stones 84 are annularly arranged at substantially equal intervals along the outer circumferential edge of the wheel base 82. The grinding abrasive stones 84 are formed into a rectangular parallelepiped shape, for example, and contain abrasive grains composed of diamond, cubic boron nitride (cBN), or the like and a binding material (bond material) that fixes the abrasive grains. As the binding material, a metal bond, a resin bond, a vitrified bond, or the like can be used. However, there is no limitation on the number, shape, material, size, and so forth of the grinding abrasive stones 84.

The grinding wheel 80 rotates around a rotation axis substantially parallel to the vertical direction by power transmitted from the rotational drive source through the spindle 76 and the mount 78. Furthermore, a movement mechanism (not illustrated) of a ball screw system that raises and lowers the grinding unit 74 along the vertical direction is coupled to the grinding unit 74. Moreover, a nozzle 86 that supplies a grinding liquid 88 such as purified water to the wafer 11 and the grinding abrasive stones 84 is disposed near the grinding unit 74.

When the wafer 11 is ground by the grinding apparatus 70, first, the wafer 11 is held by the holding table 72. Specifically, the wafer 11 is disposed over the holding table 72 in such a manner that the side of the front surface 11a faces the holding surface 72a and the side of the back surface 11b is exposed upward. When a suction force (negative pressure) of the suction source is caused to act on the holding surface 72a in this state, the side of the front surface 11a of the wafer 11 is held under suction by the holding table 72. When the wafer 11 is held by the holding table 72, a protective sheet 23 that protects the wafer 11 may be stuck to the side of the front surface 11a of the wafer 11. The shape, material, and so forth of the protective sheet 23 are similar to those of the protective sheet 17 (see FIG. 2).

Next, the holding table 72 is positioned below the grinding unit 74. Then, the grinding wheel 80 is lowered toward the holding table 72 while the holding table 72 and the grinding wheel 80 are each rotated in a predetermined direction at a predetermined rotation speed. The lowering speed of the grinding wheel 80 at this time is adjusted to cause the grinding abrasive stones 84 to be pressed against the wafer 11 with a proper force. When the grinding abrasive stones 84 get contact with the side of the back surface 11b of the wafer 11, the side of the back surface 11b of the wafer 11 is shaved off. As a result, the side of the back surface 11b of the wafer 11 is ground and the wafer 11 is thinned. This exposes the grooves 11c in the back surface 11b, and the wafer 11 is divided along the planned dividing lines 13. Then, when the thickness of the wafer 11 has become the finished thickness, the grinding of the wafer 11 is stopped and the grinding step S14 is completed.

Besides, structures, methods, and so forth according to the above-described embodiment can be carried out with appropriate changes without departing from the range of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A manufacturing method of chips in which a wafer segmented into a plurality of regions by a plurality of planned dividing lines set in a lattice manner is divided to manufacture the chips, the manufacturing method comprising:
a groove forming step of holding the wafer including a first surface and a second surface by a holding table and forming grooves having a depth smaller than a thickness of the wafer along the planned dividing lines on a side of the first surface of the wafer;
a first protective film coating step of coating the first surface of the wafer and side surfaces of the grooves with a first protective film after the groove forming step; and
a dividing step of dividing the wafer along the planned dividing lines after the first protective film coating step, wherein
plasma etching is executed for the wafer from the side of the first surface in the dividing step.

2. The manufacturing method of chips according to claim 1, wherein
the dividing step includes
a second protective film coating step of coating the side surfaces and bottom surfaces of the grooves with a second protective film thinner than the first protective film,
an anisotropic plasma etching step of executing anisotropic plasma etching for the wafer from the side of the first surface to expose the bottom surfaces of the grooves, and
an isotropic plasma etching step of executing isotropic plasma etching for the wafer from the side of the first surface to etch the bottom surfaces of the grooves.

3. The manufacturing method of chips according to claim 1, further comprising:
a protective film removal step of removing parts that coat bottom surfaces of the grooves in the first protective film to expose the bottom surfaces of the grooves by executing plasma etching for the wafer from the side of the first surface after the first protective film coating step and before the dividing step.

4. The manufacturing method of chips according to claim 1, further comprising:
a plasma etching step of executing plasma etching for the wafer from the side of the first surface in a state in which the grooves are exposed after the groove forming step and before the first protective film coating step.

5. The manufacturing method of chips according to claim 1, wherein
the grooves are formed in such a manner that an aspect ratio B/A of a width A of the grooves and a depth B of the grooves becomes equal to or higher than 1 in the groove forming step.

6. The manufacturing method of chips according to claim 1, wherein,
in the dividing step, the wafer is divided along the planned dividing lines by executing the plasma etching for the wafer until the grooves reach the second surface of the wafer.

7. The manufacturing method of chips according to claim 1, wherein,
in the dividing step, the wafer is divided along the planned dividing lines by grinding a side of the second surface of the wafer and exposing the grooves in the second surface of the wafer after executing the plasma etching for the wafer.

8. The manufacturing method of chips according to claim 1, wherein
the grooves are formed by causing an annular cutting blade to cut into the wafer in the groove forming step.

9. The manufacturing method of chips according to claim 1, wherein
the grooves are formed by irradiating the wafer with a laser beam having absorbability with respect to the wafer in the groove forming step.
